(19) United States
(12) Patent Application Publication
(10) Pub. No.: US 2023/0162995 A1
(43) Pub. Date: May 25, 2023

(54) Method for Improving Stability of Etching Rate of Etching Chamber

(71) Applicant: Shanghai Huali Microelectronics Corporation, Shanghai (CN)

(72) Inventors: Kaiqu Ang, Shanghai (CN); Zaifeng Tang, Shanghai (CN); Jin Xu, Shanghai (CN)

(73) Assignee: Shanghai Huali Microelectronics Corporation, Shanghai (CN)

(21) Appl. No.: 17/896,286

(22) Filed: Aug. 26, 2022

(30) Foreign Application Priority Data
Nov. 24, 2021 (CN) 202111399235.9

(51) Int. Cl. H01L 21/67

(52) U.S. Cl. CPC H01L 21/67063

(57) ABSTRACT

The present application discloses a method for improving stability of etching rate of an etching chamber, which includes the following steps: step 1: providing a first focusing ring with a one-piece structure; step 2: performing a fatigue damage test to the first focusing ring; step 3: disposing a second focusing ring with a two-piece structure according to the damage range, the second focusing ring consisting of a first concentration ring and a second outer protection ring, the material of the first concentration ring being the same as the material of the first focusing ring, the diameter of the outer edge of the first concentration ring extending to a position where the damage range is at least completely covered; step 4: performing an etching process by adopting the etching chamber with the second focusing ring.

### CROSS-REFERENCES TO RELATED APPLICATIONS

This application claims the priority to Chinese patent application No. 202111399235.9, filed on Nov. 24, 2021, the disclosure of which is incorporated herein by reference in its entirety.

### TECHNICAL FIELD

The present application relates to a method for manufacturing a semiconductor integrated circuit, in particular to a method for improving stability of etching rate of an etching chamber.

### BACKGROUND

As the integrated circuit technology enters the era of very large scale integration, the semiconductor wafer process is gradually transitioning to 12 inch or larger size. With the continuous increase of wafer size, the stability of vacuum reaction process chamber is required to be higher and higher. In the design of the etching process chamber, i.e., the etching chamber, in order to ensure the uniformity in the etched chip, a focusing ring is usually designed around the wafer, and a similar material with a different structure is used to manufacture the focusing ring. The similar material is to ensure that the etching uniformity of the edge is maintained, and the structural difference is mainly to ensure the etching selectivity to ensure the service life of the focusing ring component.

The structure of the focusing ring includes one-piece structure and two-piece structure.

Referring to FIG. 1, it is a schematic diagram of a structure of an existing focusing ring with a one-piece structure. A wafer placement part is provided on a focusing ring 101. The wafer placement part is disposed close to an inner edge of the focusing ring 101. In the etching process, the wafer 104 is placed on the wafer placement part of the first focusing ring 101. FIG. 1 only illustrates a sectional view of the focusing ring 101 in a radial direction. In a top view, the focusing ring 101 is in an annular structure.

A pedestal is provided in the etching chamber. The first focusing ring 101 sleeves the pedestal. In FIG. 1, a bottom electrode 102 and an insulating ring 103 are further provided on the pedestal.

Referring to FIG. 2, it is a schematic diagram of a structure of an existing focusing ring with a two-piece structure. The two-piece structure of the focusing ring 201 consists of a first concentration ring 201a and a second outer protection ring 201b. FIG. 2A only illustrates a sectional view of the focusing ring 201 in a radial direction. In a top view, the focusing ring 201 is in an annular structure.

A wafer placement part is provided on the focusing ring 201. The wafer placement part is disposed close to the inner edge of the focusing ring 201. In the etching process, the wafer 204 is placed on the wafer placement part of the first focusing ring 201.

A pedestal is provided in the etching chamber. The first focusing ring 201 sleeves the pedestal. In FIG. 1, a bottom electrode 202 and an insulating ring 203 are further provided on the pedestal.

The material of the first concentration ring 201a is selected according to the material of an etching film layer. The material of the first focusing ring 201a is required to ensure that an etching rate deviation of an edge meets a first required value when the material of the etching film layer is etched.

The second outer protection ring 201b is to improve the service life of the entire focusing ring 201 and reduce the cost.

Taking the Front-End-Of-Line (FEOL) etching process as an example, it mainly etches Si and SiN films, which is mainly realized by adopting an Inductive Coupled Plasma (ICP) chamber, and the focusing ring is a quartz focusing ring. That is, in the structure illustrated in FIG. 1, the material of the first focusing ring 101 is quartz.

In the structure illustrated in FIG. 2A, the material of the first concentration ring 201a is quartz; the material of the second outer protection ring 201b is ceramic, and the material of the ceramic includes aluminum oxide (Al₂O₃) or yttrium oxide (Y₂O₃).

In the structure illustrated in FIG. 2A, because the second outer protection ring 201b has a long service life, the component cost can be greatly reduced. However, the focusing ring illustrated in FIG. 2A will cause the problem of unstable etching rate of the etching process.

In the actual production process of the machine, the focusing ring with the two-piece structure is designed in the high bias voltage process, and the etching rate has the abnormality of poor stability of the etching rate, such as deviation of more than 10%. The main reason is that the plasma will bombard the ceramic material of the second outer protection ring 201b under the high bias voltage, and the metal in the ceramic material will be deposited on the inner wall of the chamber, thus affecting the etching rate.

Referring to FIG. 2B, it is a schematic diagram of a deposition phenomenon of an existing focusing ring with a two-piece structure in the etching process. The etching chamber also includes a plasma concentration cover 205 and a top electrode 206. The ions of the plasma 207 will bombard downwards under the action of the top electrode 206 and the bottom electrode 202. At the edge of the wafer 204, the density of the plasma 207 remains the same. The density of the plasma 207 will gradually decrease to zero at a position above the middle area of the first concentration ring 201a. In this way, the second outer protection ring 201b located on the outer side of the first concentration ring 201a will also be bombarded by the ions of the plasma 207, and the ion bombardment action will increase with the increase of the bias voltage. As illustrated by the arrow line 208, under the action of ion bombardment, the material of the second outer protection ring 201b, such as the metal yttrium represented by a reference sign 209, will be bombarded out and deposited on the inner surface of the etching chamber, such as the surface of the plasma concentration cover 205 and the top electrode 206. With the increase of the etching process time experienced by the etching chamber, the amount of yttrium deposited in the etching chamber will increase, which will finally affect the stability of the etching rate.

### BRIEF SUMMARY

According to some embodiments in this application, the present application is to provide a method for improving stability of etching rate of an etching chamber, which can adopt a focusing ring with a two-piece structure, thus reducing the process cost and making the structure of the focusing ring be adjusted to meet the requirement on the stability of the etching rate.

The method for improving the stability of the etching rate of the etching chamber provided by the present application comprises the following steps:

step 1: providing a first focusing ring, the first focusing ring being in a one-piece structure, the material of the first focusing ring being selected according to the material of an etching film layer, and the material of the first focusing ring being required to ensure that an etching rate deviation of an edge meets a first required value when the material of the etching film layer is etched;

step 2: performing a fatigue damage test to the firs focusing ring in the etching chamber by adopting an etching process of the etching film layer to obtain a damage range of the first focusing ring;

step 3: disposing a second focusing ring according to the damage range, the second focusing ring being in a two-piece structure, the two-piece structure of the second focusing ring consisting of a first concentration ring and a second outer protection ring, and the material of the first concentration ring being the same as the material of the first focusing ring;

the service life of the material of the second outer protection ring being longer than the service life of the material of the first concentration ring;

an outer edge of the first concentration ring being located between an outer edge and an inner edge of the second outer protection ring, and the part of the first concentration ring extending outside the inner edge of the second outer protection ring being located on a surface of the second outer protection ring;

the diameter of the outer edge of the first concentration ring extending to a position where the damage range is at least completely covered, so that the exposed surface of the second outer protection ring is located on an outer side of the damage range;

step 4: performing an etching process to a wafer with the etching film layer by adopting the etching chamber with the second focusing ring, the surface of the second outer protection ring being prevented from being damaged to improve the stability of the etching rate by using a feature that the exposed surface of the second outer protection ring is located on an the outer side of the damage range.

In some cases, in step 1, the material of the etching film layer comprises Si or SiN, and the material of the first focusing ring is quartz.

In some cases, in step 1, the material of the etching film layer comprises an LK material, SiO2, Si, SiN or SiCN, and the material of the first focusing ring is polysilicon.

In some cases, in step 1, the material of the etching film layer comprises Al or TiN, the material of the first focusing ring is a ceramic material, and the ceramic material comprises aluminum oxide or yttrium oxide.

In some cases, in step 2, in the fatigue damage test, bias voltage in the etching process of the etching film layer is the highest bias voltage.

In some cases, in step 2, in the fatigue damage test, the total duration of the etching process of the etching film layer is an MTBC cycle, and the MTBC cycle represents mean time between clean of the etching chamber.

In some cases, in step 2, the damage range is obtained by measuring the thickness of the first focusing ring after the fatigue damage test is completed, the greater the decrease of the thickness, the greater the damage, and the damage range is a range in which the thickness of the first focusing ring is less than a second required value.

In some cases, the second required value is required to ensure that the etching rate deviation of the edge in step 4 meets the first required value.

In some cases, the first required value is 3%.

In some cases, in step 3, the radius of the outer edge of the first concentration ring is realized by adding a redundant window based on the radius of the outer edge of the damage range, and the redundant window is the spacing between the outer edge of the first concentration ring and the outer edge of the damage range.

In some cases, the redundant window is 50% of the spacing between the outer edge of the first focusing ring and the outer edge of the damage range.

In some cases, a first wafer placement part is provided on the first focusing ring, the first wafer placement part is disposed close to the inner edge of the first focusing ring, and the wafer is placed on the first wafer placement part of the first focusing ring in the etching process.

In some cases, a second wafer placement part is provided on the first concentration ring of the second focusing ring, the second wafer placement part is disposed close to the inner edge of the first concentration ring, and the wafer is placed on the second wafer placement part of the first concentration ring in the etching process.

In some cases, in step 3, the material of the second outer protection ring is a ceramic material and the ceramic material comprises aluminum oxide or yttrium oxide.

In some cases, a pedestal is provided in the etching chamber;

in step 1, the first focusing ring sleeves the pedestal;

in step 4, the second focusing ring sleeves the pedestal.

The present application firstly uses the first focusing ring with the one-piece structure to perform the fatigue damage test to obtain the damage range corresponding to the etching process, then disposes the second focusing ring with the two-piece structure according to the damage range, and disposes the exposed surface of the second outer protection ring in the second focusing ring outside the damage range, so as to prevent the material of the second outer protection ring from being etched and deposited on the inner surface of the etching chamber in the etching process, thus preventing the adverse effect on the stability of the etching rate of the etching process after the material of the second outer protection ring is deposited on the inner surface of the etching chamber, and ensuring that the second focusing ring can meet the requirement on the stability of the etching rate. Therefore, the present application can adopt the focusing ring with the two-piece structure, thus reducing the process cost, and making the structure of the focusing ring be adjusted to meet the requirement on the stability of the etching rate.

### BRIEF DESCRIPTION OF THE DRAWINGS

The present application will be further described below in detail combination with the specific embodiments with reference to the drawings.

FIG. 1 illustrates a schematic diagram of a structure of an existing focusing ring with a one-piece structure.

FIG. 2A illustrates a schematic diagram of a structure of an existing focusing ring with a two-piece structure.

FIG. 2B illustrates a schematic diagram of an existing focusing ring with a two-piece structure in an etching process.

FIG. 3 illustrates a flowchart of a method for improving stability of etching rate of an etching chamber according to an embodiment of the present application.

FIG. 4 illustrates a schematic diagram of a structure of a first focusing ring adopted in a method for improving stability of etching rate of an etching chamber according to an embodiment of the present application.

FIG. 5 illustrates a curve of thickness of a first focusing ring measured after a fatigue damage test in a method for improving stability of etching rate of an etching chamber according to an embodiment of the present application.

FIG. 6 illustrates a schematic diagram of a structure of a second focusing ring adopted in a method for improving stability of etching rate of an etching chamber according to an embodiment of the present application.

FIG. 7 illustrates a curve of change of etching rate of an etching process with etching process time experienced by an etching chamber when a second focusing ring in a method for improving stability of etching rate of an etching chamber according to an embodiment of the present application is adopted, and a curve of change of etching rate of an etching process with etching process time experienced by an etching chamber when the existing focusing ring with the two-piece structure in FIG. 2A is adopted.

### DETAILED DESCRIPTION

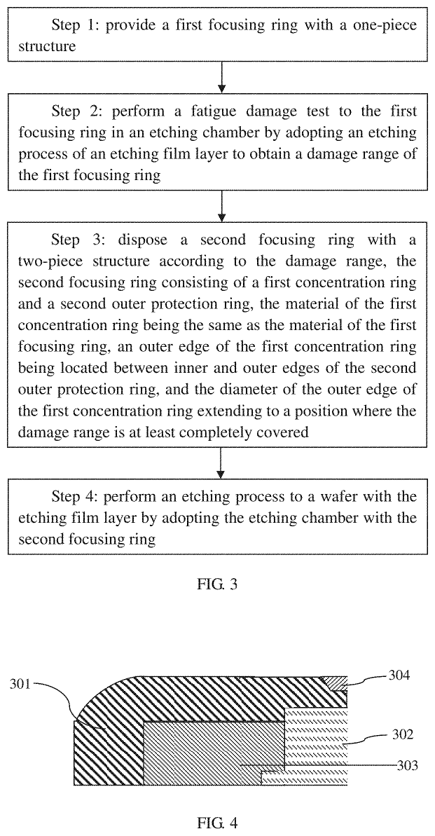

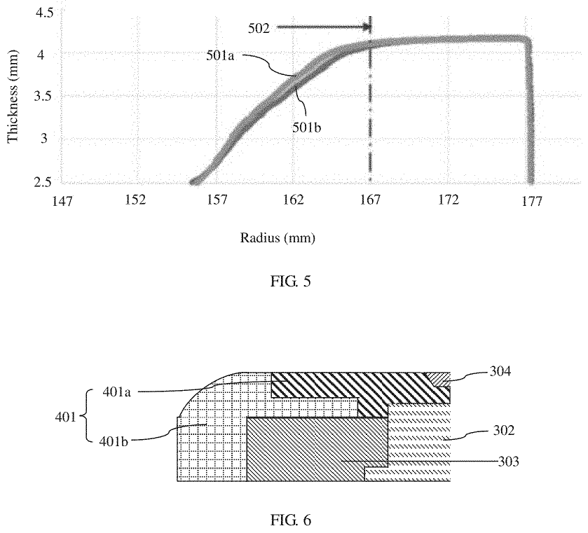

Referring to FIG. 3, it illustrates a flowchart of a method for improving stability of etching rate of an etching chamber according to an embodiment of the present application. Referring to FIG. 4, it illustrates a schematic diagram of a structure of a first focusing ring 301 adopted in the method for improving the stability of the etching rate of the etching chamber according to the embodiment of the present application. Referring to FIG. 5, it illustrates a curve of thickness of a first focusing ring measured after a fatigue damage test in the method for improving the stability of the etching rate of the etching chamber according to the embodiment of the present application. Referring to FIG. 6, it illustrates a schematic diagram of a structure of a second focusing ring 401 adopted in the method for improving the stability of the etching rate of the etching chamber according to the embodiment of the present application. The method for improving the stability of the etching rate of the etching chamber according to the embodiment of the present application comprises the following steps:

In step 1, referring to FIG. 4, a first focusing ring 301 is provided. The first focusing ring 301 is in a one-piece structure. The material of the first focusing ring 301 is selected according to the material of an etching film layer. The material of the first focusing ring 301 is required to ensure that an etching rate deviation of an edge meets a first required value when the material of the etching film layer is etched. FIG. 4 illustrates only a sectional view of the first focusing ring 301 in a radial direction. In a top view, the first focusing ring 301 is in an annular structure.

In some embodiments, the first required value is 3%.

In some embodiments, the material of the etching film layer comprises Si or SiN, and the material of the first focusing ring 301 is quartz.

In other embodiments, the material of the etching film layer comprises an LK material, SiO2, Si, SiN or SiCN, and the material of the first focusing ring 301 is polysilicon.

In other embodiments, the material of the etching film layer comprises Al or TiN, the material of the first focusing ring 301 is a ceramic material, and the ceramic material comprises aluminum oxide or yttrium oxide.

Taking FEOL as an example, the etching film layer in FEOL is usually a Si and SiN film layer, the etching chamber is mainly implemented by adopting an ICP chamber, and the material of the first focusing ring 301 is quartz, that is, the first focusing ring 301 is a quartz focusing ring.

A first wafer placement part is provided on the first focusing ring 301. The first wafer placement part is disposed close to the inner edge of the first focusing ring 301. The wafer 304 is placed on the first wafer placement part of the first focusing ring 301 in the etching process.

A pedestal is provided in the etching chamber. The first focusing ring 301 sleeves the pedestal. In FIG. 4, a bottom electrode 302 and an insulating ring 303 are further provided on the pedestal.

In step 2, a fatigue damage test is performed to the firs focusing ring 301 in the etching chamber by adopting an etching process of the etching film layer to obtain a damage range of the first focusing ring 301.

In some embodiments, in the fatigue damage test, bias voltage in the etching process of the etching film layer is the highest bias voltage. The highest bias voltage reaches more than 1000V.

In the fatigue damage test, the total duration of the etching process of the etching film layer is an MTBC cycle, and the MTBC cycle represents mean time between clean of the etching chamber.

The damage range is obtained by measuring the thickness of the first focusing ring 301 after the fatigue damage test is completed, the greater the decrease of the thickness, the greater the damage, and the damage range is a range in which the thickness of the first focusing ring 301 is less than a second required value. The second required value is required to ensure that the etching rate deviation of the edge in step 4 meets the first required value. Referring to FIG. 5, curves 501a and 501b are thickness curves along different radius directions of the first focusing ring 301. For example, the radius direction corresponding to curve 501a and the radius direction corresponding to curve 501b are perpendicular or have a difference of 180 degrees. It can be seen that curves 501a and 501b basically coincide, and the damage range is located in the radius range corresponding to a reference sign 502 of the first focusing ring 301. In the area outside the radius corresponding to the reference sign 502, the thickness of the first focusing ring 301 is basically unchanged or the loss is very small. If a subsequent second outer protection ring 401b is disposed in the area outside the radius corresponding to the reference sign 502, the etching rate deviation of the edge will meet the first required value. In FIG. 5, the radius corresponding to the reference sign 502 is 167 mm.

In step 3, referring to FIG. 6, a second focusing ring 401 is disposed according to the damage range. The second focusing ring 401 is in a two-piece structure. The two-piece structure of the second focusing ring 401 consists of a first concentration ring 401a and a second outer protection ring 401b. The material of the first concentration ring 401a is the same as the material of the first focusing ring 301.

FIG. 6 illustrates only a sectional view of the second focusing ring 401 in the radial direction. In the top view, the second focusing ring 401 is in an annular structure.

The service life of the material of the second outer protection ring 401b is longer than the service life of the material of the first concentration ring 401a. For example, the service life of the second outer protection ring 401b is more than 10 times the service life of the first concentration ring. Similarly, taking the FEOL process as an example, the material of the first concentration ring 401a is quartz, and the material of the second outer protection ring 401B is a ceramic material, and the ceramic material includes aluminum oxide or yttrium oxide. At this time, the service life of the first concentration ring 401a is 500 hours, and the service life of the second outer protection ring 401b is 5000 hours.

An outer edge of the first concentration ring 401a is located between an outer edge and an inner edge of the second outer protection ring 401b, and the part of the first concentration ring 401a extending outside the inner edge of the second outer protection ring 401b is located on a surface of the second outer protection ring 401b.

The diameter of the outer edge of the first concentration ring 401a extending to a position where the damage range is at least completely covered, so that the exposed surface of the second outer protection ring 401b is located on an outer side of the damage range.

In some embodiments, the radius of the outer edge of the first concentration ring 401a is realized by adding a redundant window based on the radius of the outer edge of the damage range, and the redundant window is the spacing between the outer edge of the first concentration ring 401a and the outer edge of the damage range. In some cases, the redundant window is 50% of the spacing between the outer edge of the first focusing ring 301 and the outer edge of the damage range.

A second wafer placement part is provided on the first concentration ring 401a of the second focusing ring 401, the second wafer placement part is disposed close to the inner edge of the first concentration ring 401a, and the wafer 304 is placed on the second wafer placement part of the first concentration ring 401a in the etching process.

The second focusing ring 401 sleeves the pedestal. The pedestal in FIG. 6 is the same as the pedestal in FIG. 4.

In step 4, an etching process is performed to a wafer with the etching film layer by adopting the etching chamber with the second focusing ring401. The surface of the second outer protection ring 401b is prevented from being damaged to improve the stability of the etching rate by using a feature that the exposed surface of the second outer protection ring 401b is located on an outer side of the damage range.

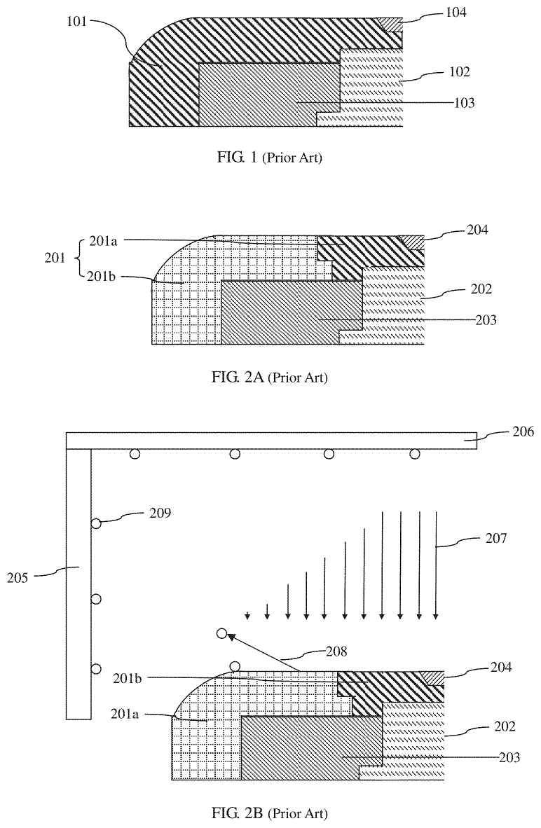

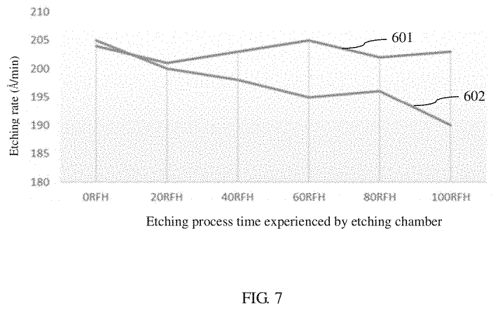

Referring to FIG. 7, it illustrates a curve 601 of change of etching rate of an etching process with etching process time experienced by the etching chamber when the second focusing ring 401 in the method for improving the stability of the etching rate of the etching chamber according to the embodiment of the present application is adopted, and a curve 602 of change of etching rate of an etching process with etching process time experienced by the etching chamber when the existing focusing ring with the two-piece structure in FIG. 2A is adopted. Take that the materials of the etching film layer corresponding to the etching process is SiN as an example. Unit RFH of the horizontal coordinate in FIG. 7 represents cumulative use hours of RF. It can be seen that as the etching process time of the etching chamber increases, the value of curve 602 will decrease, while curve 601 will maintain at a high value.

The embodiment of the present application firstly uses the first focusing ring 301 with the one-piece structure to perform the fatigue damage test to obtain the damage range corresponding to the etching process, then disposes the second focusing ring 401 with the two-piece structure according to the damage range, and disposes the exposed surface of the second outer protection ring 401b in the second focusing ring 401 outside the damage range, so as to prevent the material of the second outer protection ring 401b from being etched and deposited on the inner surface of the etching chamber in the etching process, thus preventing the adverse effect on the stability of the etching rate of the etching process after the material of the second outer protection ring 401b is deposited on the inner surface of the etching chamber, and ensuring that the second focusing ring 401 can meet the requirement on the stability of the etching rate. Therefore, the embodiment of the present application can adopt the focusing ring with the two-piece structure, thus reducing the process cost, and making the structure of the focusing ring be adjusted to meet the requirement on the stability of the etching rate.

The present application has been described in detail through the specific embodiments, which, however, do not constitute limitations to the present application. Without departing from the principle of the present application, those skilled in the art may also make many modifications and improvements, which should also be considered as included in the scope of protection of the present application.

What is claimed is:

1. A method for improving stability of an etching rate of an etching chamber, comprising:
step 1: providing a first focusing ring, the first focusing ring being in a one-piece structure, a material of the first focusing ring being selected according to a material of an etching film layer, and the material of the first focusing ring being required to ensure that an etching rate deviation of an edge meets a first required value when the material of the etching film layer is etched;
step 2: performing a fatigue damage test to the first focusing ring in the etching chamber by adopting an etching process of the etching film layer to obtain a damage range of the first focusing ring;
step 3: disposing a second focusing ring according to the damage range, the second focusing ring being in a two-piece structure, the two-piece structure consisting of a first concentration ring and a second outer protection ring, and a material of the first concentration ring being the same as the material of the first focusing ring,
a service life of a material of the second outer protection ring being longer than a service life of the material of the first concentration ring,
an outer edge of the first concentration ring being located between an outer edge and an inner edge of the second outer protection ring, and a part of the first concentration ring extending outside the inner edge of the second outer protection ring being located on a surface of the second outer protection ring,
the diameter of the outer edge of the first concentration ring extending to a position where the damage range is at least completely covered, so that an exposed surface of the second outer protection ring is located on an outer side of the damage range; and
step 4: performing an etching process to a wafer with the etching film layer by adopting the etching chamber with the second focusing ring, the surface of the second outer protection ring being prevented from being damaged to improve the stability of the etching rate by using a feature that the exposed surface of the second outer protection ring is located on an outer side of the damage range.

2. The method for improving the stability of the etching rate of the etching chamber according to claim 1, wherein, in step 1, the material of the etching film layer comprises Si or SiN, and the material of the first focusing ring is quartz.

3. The method for improving the stability of the etching rate of the etching chamber according to claim 1, wherein, in step 1, the material of the etching film layer comprises an LK material, SiO2, Si, SiN or SiCN, and the material of the first focusing ring is polysilicon.

4. The method for improving the stability of the etching rate of the etching chamber according to claim 1, wherein, in step 1, the material of the etching film layer comprises Al or TiN, the material of the first focusing ring is a ceramic material, and the ceramic material comprises aluminum oxide or yttrium oxide.

5. The method for improving the stability of the etching rate of the etching chamber according to claim 1, wherein, in step 2, in the fatigue damage test, a bias voltage in the etching process of the etching film layer is a highest bias voltage.

6. The method for improving the stability of the etching rate of the etching chamber according to claim 5, wherein, in step 2, in the fatigue damage test, a total duration of the etching process of the etching film layer is an MTBC cycle, and the MTBC cycle represents mean time between clean of the etching chamber.

7. The method for improving the stability of the etching rate of the etching chamber according to claim 6, wherein, in step 2, the damage range is obtained by measuring a thickness of the first focusing ring after the fatigue damage test is completed, the greater a decrease of the thickness, the greater the damage, and the damage range is a range in which the thickness of the first focusing ring is less than a second required value.

8. The method for improving the stability of the etching rate of the etching chamber according to claim 7, wherein the second required value is required to ensure that the etching rate deviation of the edge in step 4 meets the first required value.

9. The method for improving the stability of the etching rate of the etching chamber according to claim 8, wherein the first required value is 3%.

10. The method for improving the stability of the etching rate of the etching chamber according to claim 7, wherein, in step 3, the radius of the outer edge of the first concentration ring is realized by adding a redundant window based on the radius of the outer edge of the damage range, and the redundant window is a spacing between the outer edge of the first concentration ring and the outer edge of the damage range.

11. The method for improving the stability of the etching rate of the etching chamber according to claim 10, wherein the redundant window is 50% of the spacing between the outer edge of the first focusing ring and the outer edge of the damage range.

12. The method for improving the stability of the etching rate of the etching chamber according to claim 1, wherein a first wafer placement part is provided on the first focusing ring, the first wafer placement part is disposed close to the inner edge of the first focusing ring, and the wafer is placed on the first wafer placement part of the first focusing ring in the etching process.

13. The method for improving the stability of the etching rate of the etching chamber according to claim 12, wherein a second wafer placement part is provided on the first concentration ring of the second focusing ring, the second wafer placement part is disposed close to the inner edge of the first concentration ring, and the wafer is placed on the second wafer placement part of the first concentration ring in the etching process.

14. The method for improving the stability of the etching rate of the etching chamber according to claim 2, wherein, in step 3, the material of the second outer protection ring is a ceramic material and the ceramic material comprises aluminum oxide or yttrium oxide.

15. The method for improving the stability of the etching rate of the etching chamber according to claim 13, wherein a pedestal is provided in the etching chamber;
in step 1, the first focusing ring sleeves the pedestal; and
in step 4, the second focusing ring sleeves the pedestal.
